(19) United States
(12) Patent Application Publication
(10) Pub. No.: US 2026/0031809 A1
(43) Pub. Date: Jan. 29, 2026

(54) SWITCHING CIRCUIT, POWER MODULE UNIT, AND MOTOR CONTROLLER CIRCUIT WITH VOLTAGE MONITORING UNIT

(71) Applicant: Infineon Technologies Austria AG, Villach (AT)

(72) Inventor: Yuqiang QIU, Qingdao (CN)

(21) Appl. No.: 19/261,385

(22) Filed: Jul. 7, 2025

(30) Foreign Application Priority Data
Jul. 25, 2024 (DE) 102024207033.5

(51) Int. Cl. H03K 17/687

(52) U.S. Cl. CPC H03K 17/6871

(57) ABSTRACT

A switching circuit includes a power semiconductor device and a current mirror circuit. The power semiconductor device is in a switched current path between a switching node and a reference potential. The current mirror circuit includes a first transistor and a second transistor and copies a reference current through the first transistor by controlling an output current through the second transistor. The first transistor is electrically connected outside the switched current path and in series with the power semiconductor device in a first current path. The second transistor is in a second current path. The first current path and the second current path are electrically connected in parallel.

### CROSS-REFERENCE TO RELATED APPLICATION

This application claims priority to Germany Patent Application No. 102024207033.5 filed on Jul. 25, 2024, the content of which is incorporated by reference herein in its entirety.

### TECHNICAL FIELD

The present disclosure relates to a switching circuit for voltage monitoring of power semiconductor devices. The switching circuit can be combined with or integrated into a power module unit or a motor controller circuit.

### BACKGROUND

Resilience of technical systems is of paramount importance. Real-time monitoring techniques capable of tracking the status of power semiconductor devices make it possible to send a warning signal before a catastrophic system failure occurs and/or can be used for failure prediction. With some power semiconductor devices, the voltage that drops across the power semiconductor device when it is switched on provides information about the state of health/aging of the power semiconductor device. There is an ongoing need to perform reliable voltage measurements in switching circuits with power semiconductor devices during operation with little effort.

### SUMMARY

A switching circuit includes a power semiconductor device and a current mirror circuit. The power semiconductor device is in a switched current path between a switching node and a reference potential. The current mirror circuit includes a first transistor and a second transistor and copies a reference current IRef through the first transistor by controlling an output current Iout through the second transistor. The first transistor is electrically connected outside the switched current path and in series with the power semiconductor device in a first current path. The second transistor is in a second current path. The first current path and the second current path are electrically connected in parallel.

The current mirror circuit makes it possible to image the voltage drop across the power semiconductor device into a voltage drop or a combination of voltage drops across elements in the first second current path. The monitored voltages can be kept free from the high switching voltages handled by the power semiconductor device. Voltage monitoring can be performed without shunts in the switching circuit at low voltages typical for logic circuits.

A compensation pn junction can be used to map a voltage drop across the power semiconductor device to a voltage drop across one of the elements in the second current path. The second current path can be kept free from the high switching voltages that the power semiconductor device handles. The voltage across the power semiconductor device can be monitored by observing a single voltage in the low voltage domain.

Those skilled in the art will recognize additional features and advantages by reading the following detailed description and viewing the accompanying drawings.

### BRIEF DESCRIPTION OF THE DRAWINGS

The accompanying drawings are provided for further understanding of the implementations and form an integral part of this description. The drawings illustrate implementations of a switching circuit, a power module unit and a motor controller circuit and, together with the description, explain the principles underlying the implementations. Further implementations are described in the following detailed description and in the claims. Features of the various implementations may be combined with each other.

FIG. 1 is a circuit diagram of a current mirror circuit based on two npn bipolar junction transistors for discussing background useful for understanding of the implementations.

FIG. 2 is a circuit diagram of a current mirror circuit based on two pnp bipolar junction transistors for discussing background useful for understanding of the implementations.

FIG. 3 is a circuit diagram of a switching circuit with a power semiconductor device and a current mirror circuit based on two npn bipolar junction transistors in accordance with an implementation.

FIG. 4 is a circuit diagram of a switching circuit with a power semiconductor device and a current mirror circuit based on two npn bipolar junction transistors and with high voltage diodes in accordance with an implementation.

FIG. 5 is a circuit diagram of a switching circuit with a power semiconductor device and a current mirror circuit based on two pnp bipolar junction transistors and with high voltage diodes in accordance with an implementation.

FIG. 6 is a circuit diagram of a switching circuit with a power semiconductor device and a current mirror circuit based on two npn bipolar junction transistors and with a compensation pn junction in accordance with an implementation.

FIG. 7 is a circuit diagram of a switching circuit with a power semiconductor device and a current mirror circuit based on two n channel field effect transistors (FETs) and with a compensation FET in accordance with an implementation.

FIG. 8 is a circuit diagram of a switching circuit with a power semiconductor device and a current mirror circuit based on two pnp bipolar junction transistors and with a compensation pn junction in accordance with an implementation.

FIG. 9 is a circuit diagram of a switching circuit with a power semiconductor device and a current mirror circuit based on two p channel FETs and with a compensation FET in accordance with an implementation.

FIG. 10 is a simplified circuit diagram of a power module unit having a switching circuit with a power semiconductor device, a current mirror circuit based on two npn bipolar junction transistors, and a voltage monitoring unit in accordance with an implementation related to a measurement across a transistor load path in an output branch of the current mirror circuit.

FIG. 11 is a simplified circuit diagram of a motor controller circuit having a switching circuit with a power semiconductor device, a current mirror circuit based on two npn bipolar junction transistors, and a voltage monitoring unit in accordance with an implementation including a measurement across a compensation pn junction in an output branch of the current mirror circuit.

FIG. 12 is a schematic diagram of a multi-device package integrating three transistors in accordance with an implementation.

FIG. 13 is a schematic diagram of a multi-diode package integrating two matching diodes in accordance with an implementation.

FIG. 14 is a simplified circuit diagram of an integrated gate driver support circuit in accordance with an implementation.

### DETAILED DESCRIPTION

In the following detailed description, reference is made to the accompanying drawings which form a part of this document and in which certain implementations of a switching circuit, a power module unit and a motor controller circuit are shown as illustrations. Structural or logical changes may be made to the illustrated implementations without departing from the scope of the present disclosure. For example, features shown or described for one implementation may be used on or in conjunction with other implementations, resulting in another implementation. The present disclosure is intended to include such modifications and variations. The implementations are described in a manner that should not be construed as limiting the scope of the appended claims. The drawings are not to scale and are for illustrative purposes only. Corresponding elements are designated by the same reference numerals in the various drawings, unless otherwise indicated.

The terms “having”, “containing”, “including”, “including” and the like are open-ended, and the terms indicate the presence of certain structures, elements or features but do not preclude the presence of additional elements or features. The articles “a”, “an” and “the” include both the plural and singular, unless the context clearly indicates otherwise.

The term “directly electrically connected” may describe a permanent low-resistive ohmic connection between the directly electrically connected elements, for example a direct contact between the elements concerned or a low-resistive connection via a metal and/or heavily doped semiconductor material.

The terms “signal-connected” and “electrically coupled” may include a permanent low-resistive ohmic connection between electrically connected elements, for example a direct contact between the concerned elements or a low-resistive connection via a metal and/or heavily doped semiconductor material, but do not preclude the presence of further passive and/or active elements in the signal path between the “signal-connected” or “electrically coupled” elements. For example, the further elements may include resistors, resistive conductor lines, capacitors and/or inductors, transistors, semiconductor diodes, Schottky diodes, transformers, opto-couplers and other.

The term “power semiconductor device” refers to semiconductor devices with a voltage blocking capability of at least 30 V, for example 48 V, 100 V, 600 V, 1.6 kV, 3.3 kV or more and with a nominal on-state current or forward current of at least 200 mA, for example 1 A, 10 A, or more.

The present disclosure concerns a switching circuit. that may include a power semiconductor device and a current mirror circuit. The power semiconductor device is in a switched current path between a switching node and a reference potential. The current mirror circuit may include a first transistor and a second transistor and may copy a reference current IRef through the first transistor by controlling an output current Iout through the second transistor. The first transistor may be electrically connected outside the switched current path and in series with the power semiconductor device in a first current path. The second transistor may be in a second current path. The first current path and the second current path may be electrically connected in parallel.

The power semiconductor device may be a field effect transistor (FET), e.g., an insulated gate field effect transistor with (IGFET) such as a silicon metal oxide semiconductor FET (Si-MOSFET) or a silicon carbide metal oxide semiconductor FET (SiC-MOSFET), a high electron mobility transistor (HEMT), or an insulated gate bipolar transistor (IGBT), by way of example.

The potential of the switching node may change between a high potential and a low potential. For example, the switching node may be the switching node of a half bridge including a high side switch and a low side switch electrically connected in series between a high potential and the reference potential GND.

The controlled load path between the load terminals of the power semiconductor device is electrically connected between the switching node and the reference potential. The controlled load path may be the emitter-collector path of an IGBT or the source-drain path of a FET or HEMT. Apart from parasitic elements, the controlled load path of the power semiconductor device may be the only component in the switched current path. A first load terminal, e.g., the collector of an IGBT or the drain of a FET may be directly connected to the switching node and the emitter of the IGBT or the source of the FET may be directly connected to the reference potential.

A controlled load path of the first transistor of the current mirror circuit is electrically connected in series with the controlled load path of the power semiconductor device and outside the switched current path. In the on state of the power semiconductor device, a total current flowing through the controlled load path of the power semiconductor device includes a switching current Isw flowing between the switching node and the reference potential, and the reference current Iref.

The first transistor and the second transistor may be a matched transistor pair with identical nominal characteristics and absolute maximum ratings and can be arranged in such a way that no junction temperature difference or only a marginal junction temperature difference can develop between the first transistor and the second transistor. Then an output current Iout through the controlled load path of the second transistor adjusts to the reference current Iref through the controlled load path of the first transistor of the current mirror.

When the power semiconductor device is switched on, the total current through the power semiconductor device generates a drop voltage Vdrop across the controlled load path of the power semiconductor device. Since the total voltage drop in the loop of the first current path is equal to the total voltage drop in the loop of the parallel second current path, the drop voltage Vdrop effects the voltages across active devices in the second current path. From one or more voltage measurements across active devices in the second current, a conclusion can be drawn about the drop voltage Vdrop.

According to an implementation, the switching circuit may further include a voltage monitoring unit configured to monitor a voltage in the second current path.

The voltage monitoring unit may include a comparator comparing a voltage obtained from the second current path with one or more threshold voltages. Alternatively, the voltage monitoring unit may include an analog-to-digital converter converting the voltage in the second current path into a digital voltage value.

Voltages may be tapped from more than two nodes of the first and/or second current paths, wherein the voltage monitoring unit may include a voltage subtractor circuit for combining more than one tapped voltage. Alternatively, one or two voltages can be tapped from the second current path and directly passed to the voltage monitoring unit. The voltage to be monitored may be tapped at terminals of the second transistor. The voltage monitoring unit may be a separate circuit or may be integrated in a gate driver integrated circuit, or in a motor controller integrated circuit.

According to an implementation, the switching circuit may further include a compensation pn junction, wherein the compensation pn junction and the second transistor are electrically connected in series in the second current path.

The compensation pn junction is electrically connected in series with the controlled load path of the second transistor. A cathode side of the compensation pn junction and the second transistor may be directly electrically connected to each other.

When the forward characteristics of the compensation pn junction and corresponding characteristics of the second transistor of the current mirror circuit are sufficiently similar, the forward voltage drop across the compensation pn junction can be nearly identical with a voltage drop between base and emitter or between gate and source of the second transistor. A single voltage measurement in the second current path may be sufficient to determine the drop voltage.

According to an implementation, the compensation pn junction may include an auxiliary transistor in diode configuration, wherein a base-emitter junction or body-source junction of the auxiliary transistor and the second transistor are electrically connected in series.

A transistor in the diode configuration is diode-connected. A diode-connected transistor is made by directly connecting the base and collector of a BJT, or the gate and drain of an IGFET.

The first transistor, the second transistor, and the auxiliary transistor may be matched transistors with identical or almost identical nominal characteristics and absolute maximum ratings and can be arranged in such a way that no junction temperature difference or almost no junction temperature difference can develop between the first transistor, the second transistor, and the auxiliary transistor. Then a base-to-emitter voltage of the auxiliary transistor and a base-to-emitter voltage of the second transistor of a bipolar junction transistor (BJT)type, or a gate-to-source voltage of the auxiliary transistor and a gate-to-source voltage of the second transistor of an insulated gate field effect transistor type are always sufficiently identical that the drop voltage Vdrop can be obtained from a single voltage measurement in the second current path.

According to an implementation, the compensation pn junction, the first transistor and the second transistor may be integrated in a multi-device package.

Integrating the first transistor, the second transistor, and the auxiliary transistor in a single package may reduce differences between the junction temperatures between the first transistor, the second transistor, and the auxiliary transistor.

According to an implementation, the switching circuit may further include a voltage supply circuit configured to supply an auxiliary supply voltage across the first current path and the second current path.

The voltage supply circuit may be a dedicated circuit for the only purpose to supply the auxiliary supply voltage to the first and second current paths of the switching circuit. Alternatively, the voltage supply circuit may be a supply circuit used to supply further circuits, e.g., logic circuits integrated in gate driver integrated circuits and/or motor controller integrated circuits.

According to an implementation, the first current path may include further first electric elements and the second current path may include further second electric elements, wherein for a predefined current a first voltage drop across the first electric elements and a second voltage drop across the second electric elements may be equal or almost equal.

The further first and second electric elements may include resistors, diodes, and/or further transistors. Each further first electric element may have a corresponding further second electric element. The first voltage drop is the total voltage drop across all further first electric elements. The second voltage drop is the total voltage drop across all further second electric elements. For any arbitrary current within a current range of interest, each voltage drop across one of the further first elements can be equal or almost equal to a voltage drop across the corresponding further second element.

When for each current within the current range of interest, a current generates the same voltage drop across symmetrical elements in the first and second current paths, the voltage monitored in the second current path can be a linear function or even an identity function of the drop voltage across the power semiconductor switch in the on-state.

According to an implementation, an ohmic resistance in the first current path and an ohmic resistance in the second current path deviate from each other by no more than 5% of an average value of the ohmic resistances.

For example, the ohmic resistance in the first current path and the ohmic resistance in the second current path deviate from each other by no more than 2% or 1% of an average value of the ohmic resistances.

The less a difference between the ohmic resistance in the first current path and an ohmic resistance in the second current path is, the simpler is the relationship between the voltage monitored in the second current path and the drop voltage Vdrop.

According to an implementation, the switching circuit may further include a first diode in the first current path and a second diode in the second current path, wherein the first diode is configured to block a blocking voltage across the power semiconductor device in an off-state of the power semiconductor device, wherein the first diode and the second diode are forward biased when the power switching device is in an on-state, and wherein the first diode and the second diode have equal nominal characteristics.

The less a difference between the forward voltages between the first diode and the second diode at the same current is, the simpler is the relationship between the voltage monitored in the second current path and the drop voltage Vdrop.

According to an implementation, the first diode and the second diode may be integrated in a multi-diode package.

Integrating the first diode and the second diode in a single package may reduce differences between the junction temperatures between the first diode and the second diode. The less a difference between the forward voltages between the first diode and the second diode depends on temperature, the better the drop voltage Vdrop can be approximated by a single voltage monitored in the second current path. The first diode and the second diode may be individual diode devices selected from the same lot and/or such that the measured diode parameters match better than for 50% of arbitrary pairs of diode devices with the same nominal characteristics. According to another example, the first diode and the second diode may be formed on the same semiconductor die.

According to an implementation, the first transistor, the second transistor, the first diode, the second diode, the further first electric elements and the further second electric elements are integrated in a multi-device package.

For example, an integrated gate driver support circuit may integrate the first transistor, the second transistor, the first diode, the second diode, the further first electric elements and the further second electric elements. Alternatively, the first transistor, the second transistor, the first diode, the second diode, the further first electric elements and the further second electric elements may be integrated in a gate driver circuit or a motor controller circuit.

According to an implementation, the first transistor and the second transistor may include bipolar junction transistors and an emitter of the first transistor and an emitter of the second transistor may be directly electrically connected to each other.

According to another implementation, the first transistor and the second transistor may include field effect transistors and a source of the first transistor and a source of the second transistor may be directly electrically connected to each other.

According to an implementation, the first transistor and the second transistor may include p channel field effect transistors or the first transistor and the second transistor may include pnp bipolar junction transistors.

According to an implementation, the switching circuit may further include a voltage monitoring unit configured to monitor a voltage across the second transistor.

According to another implementation, the first transistor and the second transistor include n channel field effect transistors or the first transistor and the second transistor include npn bipolar junction transistors.

According to an implementation, the switching circuit may further include a voltage monitoring unit electrically connected to load electrodes of the second transistor and configured to monitor a voltage across the second transistor.

According to an implementation, the switching circuit may further include a voltage monitoring unit configured to monitor a voltage between an anode side of the compensation pn junction and a network node of the first current path between the power semiconductor device and the first transistor.

Another implementation of the present disclosure is related to a power module unit. The power module unit may include a switching circuit as described above and a gate driver circuit. The gate driver circuit may drive a gate signal to a gate of the power semiconductor device. The gate driver circuit and the voltage monitoring unit may be integrated in a gate driver integrated circuit.

Another implementation of the present disclosure is related to a motor controller circuit. The motor controller circuit may include a switching circuit as described above and a motor controller that drives a H bridge including the power semiconductor device of the switching circuit, wherein the motor controller and the voltage monitoring unit are integrated in a motor controller integrated circuit.

Another implementation of the present disclosure is related to an integrated gate driver support circuit. The integrated gate driver support circuit may include a current mirror circuit that includes a first transistor and a second transistor and is configured to copy a reference current Iref through the first transistor by controlling an output current Iout through the second transistor. The first transistor is electrically connected between a sense terminal SNS and a reference terminal REF. A first diode may be electrically connected between a supply terminal V+ and a drive terminal DRV, wherein a cathode of the first diode is oriented to the drive terminal DRV. A second diode may be electrically connected is series with the second transistor between the supply terminal V+ and the reference terminal REF, wherein an anode of the second diode is oriented to the supply terminal V+. The first diode and the second diode may have equal nominal characteristics.

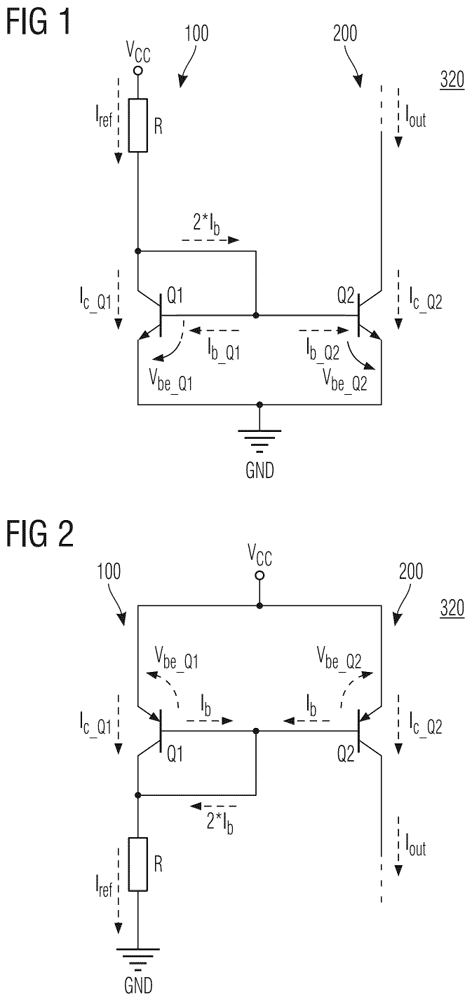

FIG. 1 shows a current mirror circuit 320 that includes a first transistor Q1 and a second transistor Q2, wherein the first and second transistors Q1, Q2 are npn bipolar junction transistors. A resistor R and a load path of the first transistor Q1 between collector and emitter are electrically connected in series in a first current path 100 between an auxiliary supply voltage VCC and a reference potential GND. A load path of the second transistor Q2 between collector and emitter is in a second current path 200 between the auxiliary supply voltage VCC and the reference potential. The emitter of the first transistor Q1 and the emitter of the second transistor Q2 are directly connected to each other and to the reference potential GND. A DC current gain β_{Q1} of the first transistor Q1 is the ratio between the collector current I_{c_Q1} and the base current I_{b_Q1} of the first transistor Q1 (Eq.(1)). A DC current gain β_{Q2} of the second transistor Q2 is the ratio between the collector current I_{c_Q2} and the base current I_{b_Q2} of the second transistor Q2 (Eq.(2)):

$${β}_{Q 1} = \frac{{I}_{c \_ Q 1}}{{I}_{b \_ Q 1}} \qquad Eq . ( 1 )$$

$${β}_{Q 2} = \frac{{I}_{c \_ Q 2}}{{I}_{b \_ Q 2}} \qquad Eq . ( 2 )$$

The first and second transistors Q1, Q2 are a matched pair of transistors, e.g., a differential pair. The nominal characteristics including the DC current gain β_{Q1} of the first transistor Q1 and the DC current gain β_{Q2} of the second transistor are identical (Eq.(3)):

$${β}_{Q 1} = {β}_{Q 2} = β \qquad Eq . ( 3 )$$

In the current mirror circuit 320, the base-to-emitter voltage V_{be_Q1} of the first transistor Q1 and the base-to-emitter voltage V_{be_Q2} of the second transistor Q2 are equal (Eq.(5)), so the base current I_{b_Q1} of the first transistor Q1 and the base current I_{b_Q2} of the second transistor Q2 are equal (Eq.(4)):

$${I}_{b \_ Q 1} = {I}_{b \_ Q 2} = {I}_{b} \qquad Eq . ( 4 )$$

$${V}_{be \_ Q 1} = {V}_{be \_ Q 2} = {V}_{b e} \qquad Eq . ( 5 )$$

As in Eq.(6), with a DC current gain β»1, a reference current Iref through the resistor R in the first current path 100 is almost equal to the collector current I_{c_Q1} of the first transistor Q1 and the collector current I_{c_Q2} of the second transistor Q2. The collector current I_{c_Q2} of the second transistor Q2 is equal to an output current Iout of the current mirror circuit 320 in the second current path:

$${I}_{r e f} ∼ {I}_{c \_ Q 1} = {I}_{c \_ Q 2} = {I}_{out} \qquad Eq . ( 6 )$$

The reference current Iref flowing through the first current path 100 generates the base-to-emitter voltage V_{be_Q1} between the base and the emitter of the first transistor Q1. The second base-to-emitter voltage V_{be_Q2} between the base and the emitter of the second transistor Q2 adjusts to the first base-to-emitter voltage V_{be_Q1}. Since the characteristics of the first and second transistors Q1, Q2 are identical, the output current Iout driven by the second transistor Q2 in the second current path 200 is equal to the reference current Iref under the assumption that the DC current gain β of both transistors Q1, Q2 is significantly greater 1.

In the current mirror circuit 320 of FIG. 2, the first transistor Q1 and the second transistor Q2 are pnp bipolar junction transistors. A load path of the first transistor Q1 between emitter and collector and a resistor R are electrically connected in series in a first current path 100 between an auxiliary supply voltage VCC and a reference potential GND. A load path of the second transistor Q2 between emitter and collector is in a second current path 200 between an auxiliary supply voltage VCC and a reference potential GND. The emitter of the first transistor Q1 and the emitter of the second transistor Q2 are directly connected to each other and to the auxiliary supply voltage VCC. The DC current gain β_{Q1} of the first transistor Q1 and the DC current gain β_{Q2} of the second transistor Q2 are defined by equations Eq.(1), Eq.(2) above.

The first and second transistors Q1, Q2 are a matched pair of transistors, e.g., a differential pair. The nominal characteristics including the DC current gain β_{Q1} of the first transistor Q1 and the DC current gain β_{Q2} of the second transistor are identical as given in equation Eq.(3) above.

The base-to-emitter voltage V_{be_Q1} of the first transistor Q1 and the base-to-emitter voltage V_{be_Q2} of the second transistor Q2 are equal and the base current I_{b_Q1} of the first transistor Q1 and the base current I_{b_Q2} of the second transistor Q2 are equal as given by equations Eq.(4) and Eq.(5).

With the DC current gain β»1, a reference current Iref through the resistor R in the first current path 100 approximates the collector current I_{c_Q1} of the first transistor Q1 and the collector current I_{c_Q2} of the second transistor Q2. The collector current I_{c_Q2} of the second transistor Q2 is equal to an output current Iout of the current mirror circuit 320 in the second current path 200 as given in equation Eq.(6).

The reference current Iref flowing through the first current path 100 generates the base-to-emitter voltage V_{be_Q1} between the base and the emitter of the first transistor Q1. The second base-to-emitter voltage V_{be_Q2} between the base and the emitter of the second transistor Q2 adjusts to the first base-to-emitter voltage V_{be_Q1}. Since the characteristics of the first and second transistors Q1, Q2 are approximately identical, the output current Iout driven by the second transistor Q2 in the second current path 200 is approximately equal to the reference current Iref under the assumption that the DC current gain β of the first and second transistors Q1, Q2 is significantly greater 1.

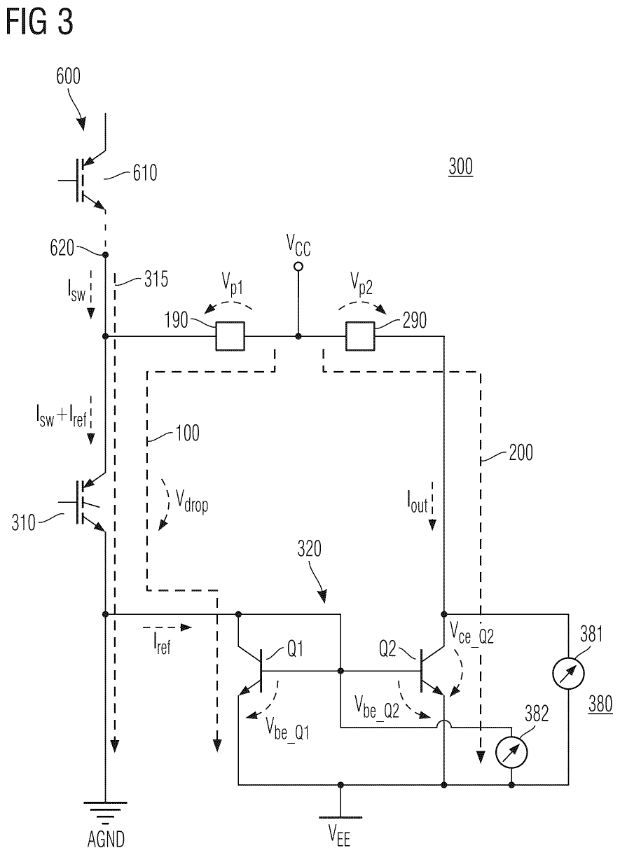

FIG. 3 shows a switching circuit 300 with a power semiconductor device 310 and a current mirror circuit 320. The power semiconductor device 310 is an IGBT operated as low side switch in a half bridge 600. In an on-state of the power semiconductor device 310, the power semiconductor device 310 conducts a switching current Isw flowing in a switched current path between a switching node 620 of the half bridge 600 and a switching reference potential AGND.

The current mirror circuit 320 includes a first transistor Q1 and a second transistor Q2. The power semiconductor device 310, the first transistor Q1 and first further elements 190 generating a first additional voltage Vₚ₁ are electrically connected in series in a first current path 100 between the auxiliary supply voltage VCC and a logic reference potential VEE. The second transistor Q2 and second further elements 290 generating a second additional voltage Vₚ₂ are electrically connected in series in a second current path 200 between an auxiliary supply voltage VCC and the logic reference potential VEE. The first current path 100 and the second current path 200 are electrically connected in parallel. The switching current Isw and a reference current Iref which flows through the first transistor Q1 generate a drop voltage Vdrop across the power semiconductor device 310. A total voltage drop in the first current path 100 is equal to the total voltage drop in the second current path 200 (Eq.(7)):

$${V}_{p 1} + {V}_{d r o p} + {V}_{be \_ Q 1} = {V}_{p 2} + {V}_{ce \_ Q 2} \qquad Eq . ( 7 )$$

The current mirror circuit 320 copies a reference current Iref which flows through the first transistor Q1 and the power semiconductor device 310 by controlling an output current Iout through the second transistor Q2. The first further elements 190 in the first current path 100 and the second further elements 290 in the second current path 200 are provided symmetrically, such that the first additional voltage Vₚ₁ caused by the reference current Iref in the first current path 100 and the second additional voltage Vₚ₂ generated by the output current Iout in the second current path 200 are identical. Equation Eq.(7) simplifies to equation Eq.(8):

$${V}_{d r o p} + {V}_{be \_ Q 1} = {V}_{ce \_ Q 2} \qquad Eq . ( 8 )$$

$${V}_{d r o p} = {V}_{ce \_ Q 2} - {V}_{be \_ Q 1} = {V}_{ce \_ Q 2} - {V}_{b {e}_{Q 2}} \qquad Eq . ( 9 )$$

The drop voltage Vdrop across the power semiconductor device 310 can be obtained by subtracting the base-to-emitter voltage V_{be_Q2} from the collector-to-emitter voltage V_{ce_Q2} (Eq.(9)). For example, the collector-to-emitter voltage V_{ce_Q2} and the base-to-emitter voltage V_{be_Q2} can be supplied to a voltage monitoring unit that includes a voltage subtractor circuit, wherein the voltage subtractor circuit produces an output voltage proportional to the voltage difference of two input signals applied to the inputs of the inverting and non-inverting terminals of an operational amplifier.

In the illustrated example, a first voltage monitoring unit 381 is electrically connected between the collector and the emitter of the second transistor Q2, and a second voltage monitoring unit 382 is electrically connected between the base and the emitter of the second transistor Q2.

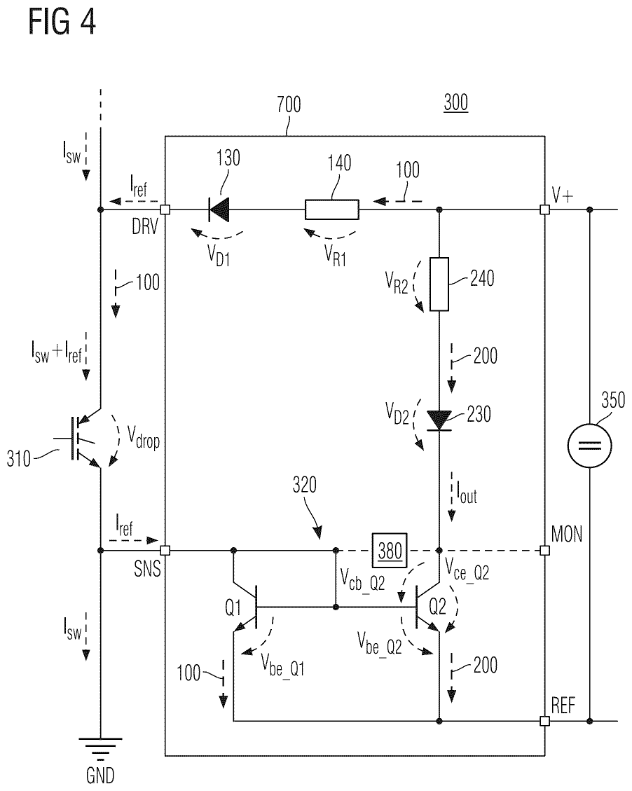

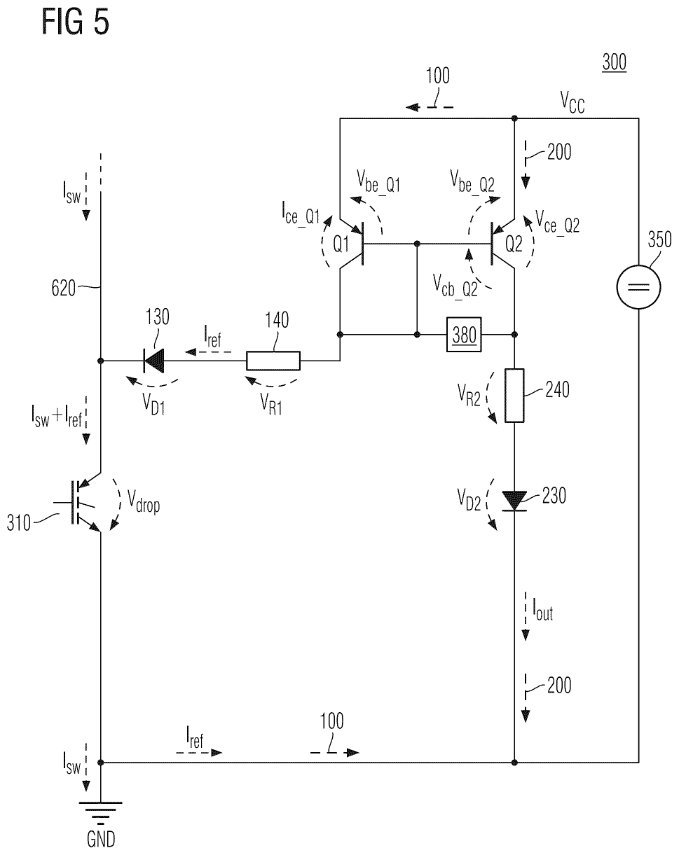

FIG. 4 shows a switching circuit 300 with the first further elements in the first current path including a first diode 130 and a first resistor 140 and the second further elements on the second current path 200 including a second diode 230 and a second resistor 240.

The first resistor 140 may include the total ohmic resistance in the first current path 100 and may include the wiring resistance and/or one or more discrete resistors. The second resistor 240 may include the total ohmic resistance in the second current path 200 and may include the wiring resistance in the second current path 200 and/or one or more discrete resistors. The first resistor 140 and the second resistor 240 have the same resistance or the resistances of the first resistor 140 and the second resistor 240 deviate from each other by not more than 5%, e.g., by not more than 2% or 1% of an average value of the two resistances. Since the reference current Iref through the first resistor 140 and the output current Iout through the second resistor 240 are equal, the voltage V_{R1} across the first resistor 140 and the V_{R2} across the second resistor 240 are equal (Eq.(10)):

$${V}_{R 1} = {V}_{R 2} = {V}_{R} \qquad Eq . ( 10 )$$

The first current path 100 includes a first diode 130 and the second current path 200 includes a second diode 230. The first diode 130 is electrically connected between the auxiliary supply voltage VCC and the power semiconductor device 310 and blocks a blocking voltage across the power semiconductor device 310 in an off-state of the power semiconductor device 310. The first diode 130 and the second diode 230 are biased in forward direction when the power switching device 310 is in an on-state.

The first diode 130 and the second diode 230 may have the same type and nominal characteristics and may show the same or almost the same dependencies of the forward voltage from the forward current such that at least in a range of interest for the reference current Iref and the output current Iout, the diode forward voltage V_{D1} across the first diode 130 and the diode forward voltage V_{D2} across the second diode 230 are equal if the reference current Iref in the first current path 100 and the output current Iout in the second current path 200 are equal (Eq.(11)):

$${V}_{D 1} = {V}_{D 2} = {V}_{D} \qquad Eq . ( 11 )$$

The total voltage drop in the first current path 100 and the total voltage drop in the second current path 200 are equal (Eq.(12)):

$${V}_{R 1} + {V}_{D 1} + {V}_{d r o p} + {V}_{be \_ Q 1} = {V}_{R 2} + {V}_{D 2} + {V}_{ce \_ Q 2} \qquad Eq . ( 12 )$$

When the output current Iout and the reference current Iref are equal, equation Eq.(12) simplifies to equation Eq.(12a):

$${V}_{d r o p} = {V}_{ce \_ Q 2} - {V}_{be \_ Q 1} = {V}_{ce \_ Q 2} - {V}_{b {e}_{Q 2}} = {V}_{cb \_ Q 2} \qquad Eq . ( 12 a )$$

A single voltage monitoring unit 380 may directly measure the collector-to-base voltage V_{cb_Q2}.

An integrated gate driver support circuit 700 may integrate the first transistor Q1, the second transistor C2, the first diode 130, the second diode 230, the first resistor 140, and the second resistor 240. The bases of the first and second transistors Q1, Q2 are directly connected to a sense terminal SNS of the integrated gate driver support circuit 700. The cathode of the first diode 130 is electrically connected to a drive output DRV. The first and second current paths 100, 200 are connected in parallel between a supply terminal V+ and a reference terminal REF.

In the illustrated example, the integrated gate driver support circuit 700 further integrates the voltage monitoring unit 380. Alternatively or in addition to the integrated voltage monitoring unit 380, the integrated gate driver support circuit 700 may include a monitor terminal MON directly connected with the collector of the second transistor Q2.

A voltage supply circuit 350 supplies the auxiliary supply voltage VCC across the first current path 100 and the second current path 200. The voltage supply circuit 350 may be electrically connected between the supply terminal V+ and the reference terminal REF.

FIG. 5 shows an equivalent switching circuit with the first transistor Q1 and the second transistor Q2 being pnp transistors. The first diode 130 and the first resistor 140 are electrically connected in series between the collector of the first transistor Q1 and the switching node 620. The second diode 230 and the second resistor 240 are electrically connected in series between the collector of the second transistor Q2 and the reference potential GND.

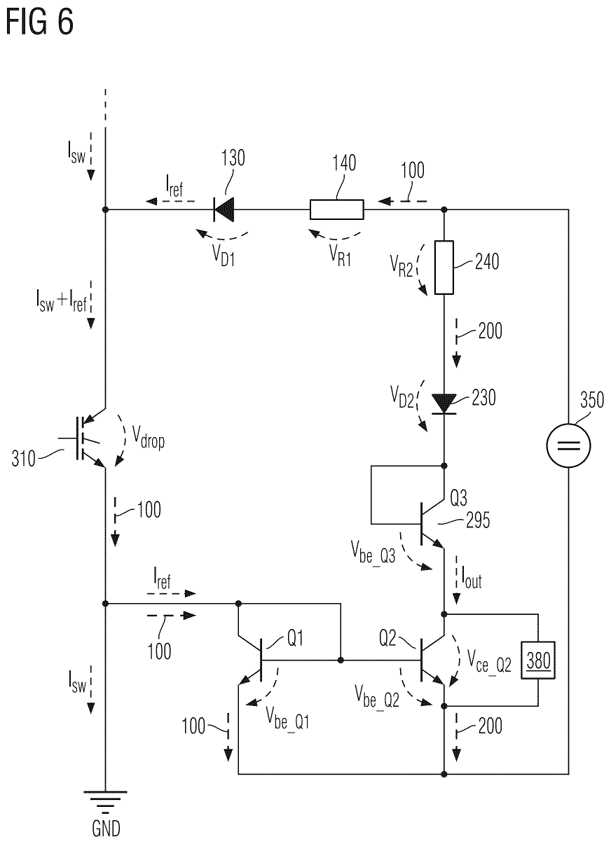

In FIG. 6, the second current path 200 includes an auxiliary transistor Q3 in diode configuration. A base-emitter junction of the auxiliary transistor Q3 and a controlled load path of the second transistor Q2 are electrically connected in series. The base-emitter junction of the auxiliary transistor Q3 forms a compensation pn junction 295, wherein the compensation pn junction 295 and the second transistor Q2 are electrically connected in series in the second current path 200. When the compensation pn junction 295 is forward biased, a compensation voltage V_{be_Q3} drops across the compensation pn junction 295. The total voltage drop along the first current path 100 and the total voltage drop along the second current path 200 are equal (Eq.13)):

$${V}_{R 1} + {V}_{D 1} + {V}_{d r o p} + {V}_{be \_ Q 1} = {V}_{R 2} + {V}_{D 2} + {V}_{be \_ Q 3} + {V}_{ce \_ Q 2} \qquad Eq . ( 13 )$$

The auxiliary transistor Q3 has the same nominal characteristics as the first transistor Q1 and the second transistor Q2. The auxiliary transistor Q3, the first transistor Q1 and the second transistor Q2 may be selected from the same lot and/or may be selected such that the measured transistor parameters match better than for 50% of arbitrary triples of transistors having the same nominal characteristics. The auxiliary transistor Q3, the first transistor Q1 and the second transistor Q2 are a matching triple. When the reference current Iref and the output current Iout are equal, the base-to-emitter voltages of the first transistor Q1, the second transistor Q2 and the auxiliary transistor Q3 are equal (Eq.(14)):

$${V}_{be \_ Q 1} = {V}_{be \_ Q 2} = {V}_{be \_ Q 3} \qquad Eq . ( 14 )$$

Equation Eq.(13) simplifies to equation Eq.(15):

$${V}_{d r o p} = {V}_{ce \_ Q 2} \qquad Eq . ( 15 )$$

The drop voltage V_{drop} is copied to the collector-to-emitter voltage V_{ce_Q2} of the second transistor Q2 and can be monitored by a single voltage monitoring unit 380 connected to the collector and the emitter of the second transistor Q2.

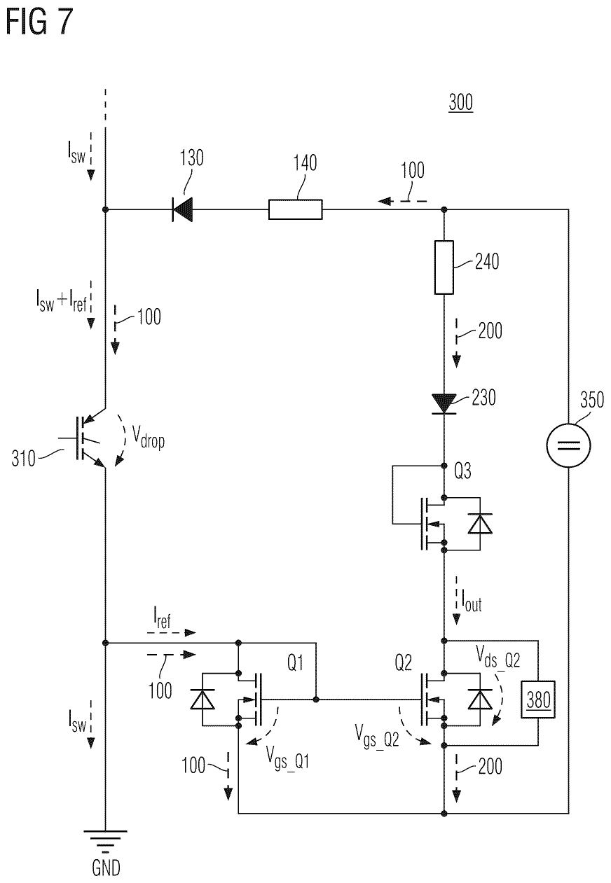

In FIG. 7, the first transistor Q1 and the second transistor Q2 are n channel field effect transistors, wherein a source of the first transistor Q1 and a source of the second transistor Q2 are directly electrically connected to each other. The drop voltage V_{drop} is copied to the drain-to-source voltage V_{ds_Q2} of the second transistor Q2.

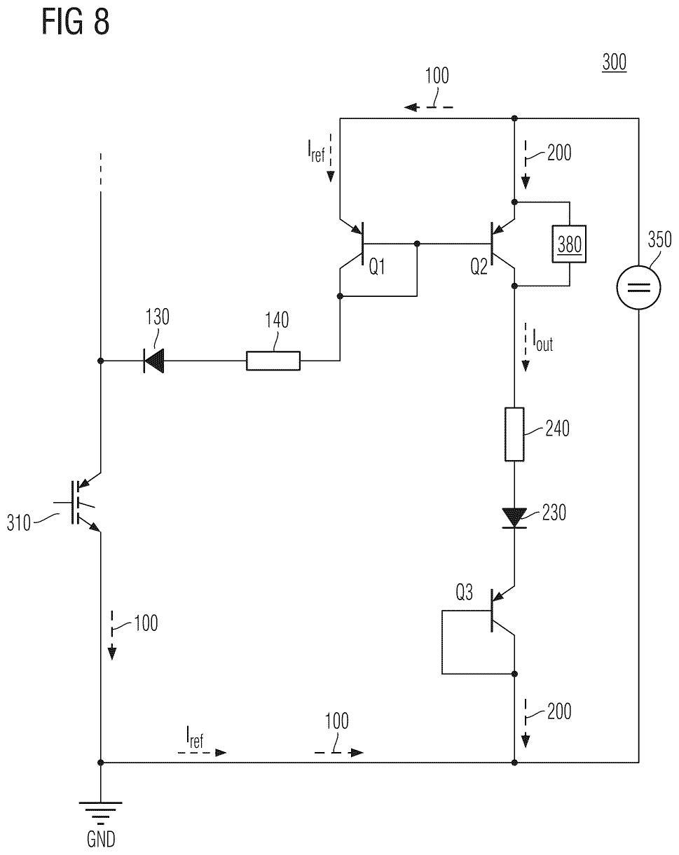

In FIG. 8, the first transistor Q1 and the second transistor Q2 are pnp bipolar junction transistors, wherein an emitter of the first transistor Q1 and an emitter of the second transistor Q2 are directly electrically connected to each other and to the auxiliary supply voltage VCC. The drop voltage V_{drop} is copied to the collector-to-emitter voltage V_{ce_Q2} of the second transistor Q2.

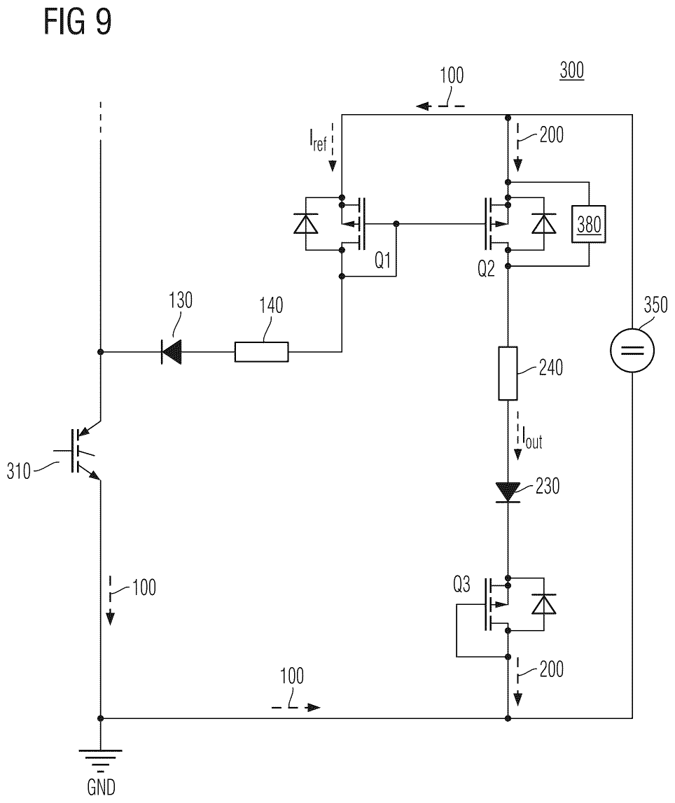

In FIG. 9, the first transistor Q1 and the second transistor Q2 are p channel field effect transistors, wherein a source of the first transistor Q1 and a source of the second transistor Q2 are directly electrically connected to each other. The drop voltage Vdrop is copied to the drain-to-source voltage V_{ds_Q2} of the second transistor Q2.

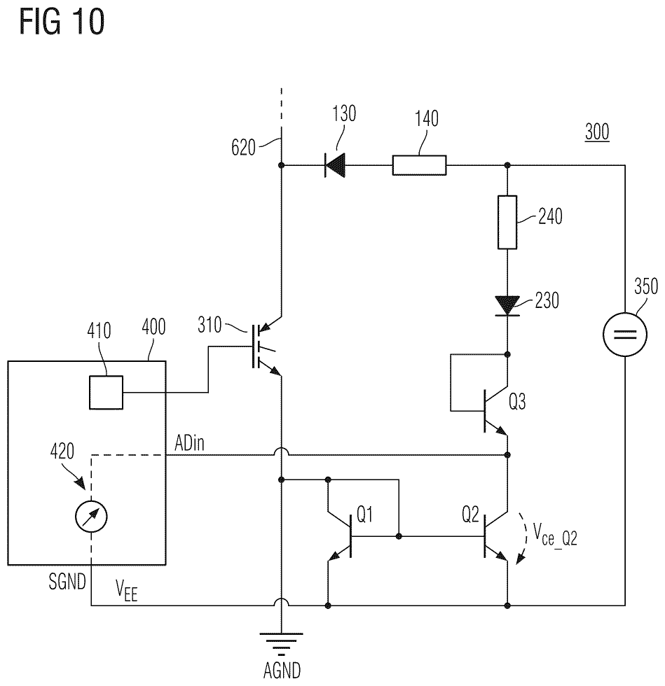

FIG. 10 shows a gate driver integrated circuit 400 integrating a gate driver circuit 410 and an analog-to-digital converter 420 used as voltage monitoring unit 380. The analog-to-digital converter 420 converts a voltage received between an analog input pin ADin and a signal ground pin SGND into a digital value. The analog input pin ADin is electrically connected to the collector of the second transistor Q2. The signal ground pin SGND is electrically connected to the emitter of the second transistor Q2 with the logic reference potential VEE. The power semiconductor device 310 is electrically connected between a switching node 620 and a switching reference potential AGND.

The signal ground pin SGND is independent from the switching reference potential AGND and can assume the potential of the emitters of the first and second transistors Q1, Q2, which is lower (more negative) than the switching reference potential AGND.

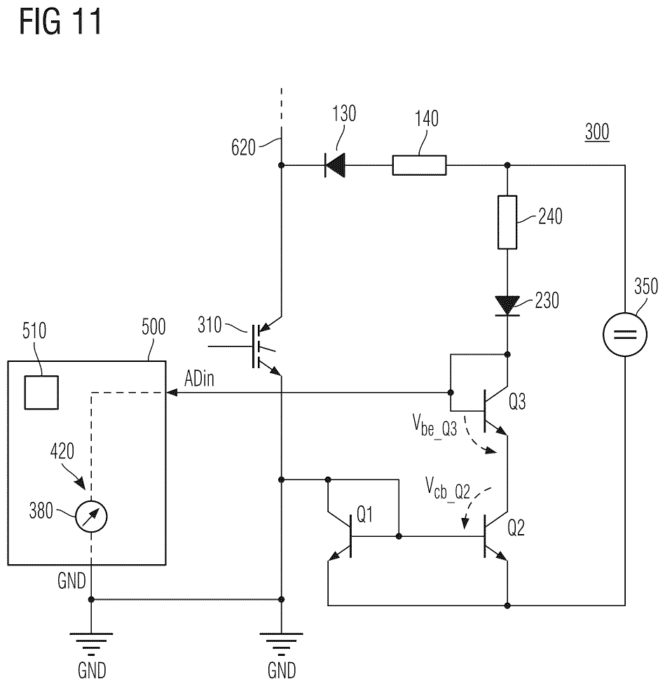

In FIG. 11, a motor controller integrated circuit 500 integrates a motor controller circuit 510 that controls a plurality of power semiconductor devices arranged to control a motor and an analog-to-digital converter 420 that converts a voltage received between an analog input pin ADin and an internal reference potential. The motor controller integrated circuit 500 has an internal connection between the internal reference potential and the reference potential GND so that the analog-to-digital converter 420 does not operate over the full swing necessary for converting the collector-to-emitter voltage V_{ce_Q2}. Considering equation Eq.(15), the drop voltage V_{drop} is equal to the sum of the collector-to-base voltage V_{cb_Q2} and the base-to-emitter voltage V_{be_Q2} of the second transistor Q2 (Eq.(16)):

$${V}_{d r o p} = {V}_{cb \_ Q 2} + {V}_{be \_ Q 2} \qquad Eq . ( 16 )$$

The second transistor Q1 and the third transistor Q3 are matching transistors (Eq.(17)):

$${V}_{be \_ Q 2} = {V}_{be \_ Q 3} \qquad Eq . ( 17 )$$

The measurement for the drop voltage Vdrop can use the base-to-emitter voltage V_{be_Q3} of the auxiliary transistor Q3 instead of the base-to-emitter voltage V_{be_Q2} of the second transistor Q2 (Eq.(18)):

$${V}_{d r o p} = {V}_{cb \_ Q 2} + {V}_{be \_ Q 3} \qquad Eq . ( 18 )$$

Accordingly, the analog input pin ADin of the motor controller integrated circuit 500 is electrically connected to the base or collector of the auxiliary transistor Q3.

The analog-to-digital converter 420 is used as voltage monitoring unit 380 as described above. The motor control integrated circuit 500 may output digital values of the drop voltage Vdrop at regular intervals or on demand via a data interface to a higher processing instance for estimating a remaining lifetime or checking for pre-failure states.

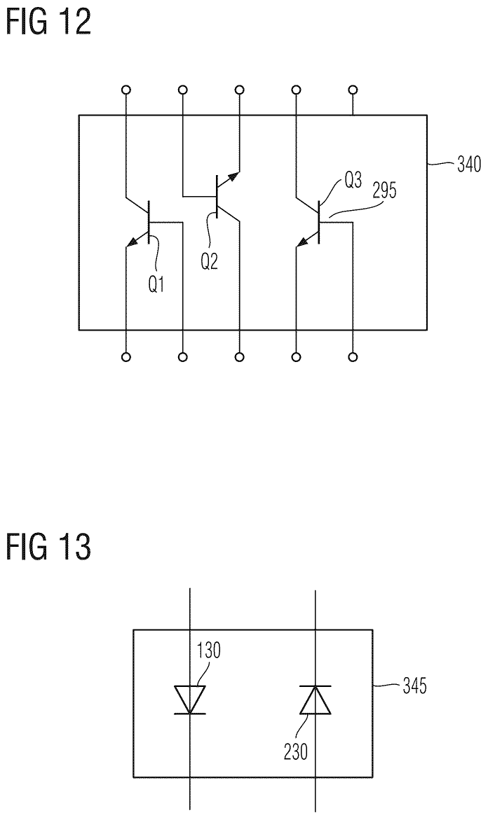

FIG. 12 shows a multi-device package 340 integrating at least the first transistor Q1, the second transistor Q2 and the auxiliary transistor Q3. In the shared multi-device package 340 the first transistor Q1, the second transistor Q2 and the auxiliary transistor Q3 are exposed to the same temperature and temperature budget so that the identity or approximative identity of the device parameters is not compromised by different junction temperatures of the first transistor Q1, the second transistor Q2 and the auxiliary transistor Q3.

If the first transistor Q1, the second transistor Q2 and the auxiliary transistor Q3 are obtained from the same semiconductor die, the characteristic parameters of the first transistor Q1, the second transistor Q2 and the auxiliary transistor Q3 can be to a high degree identical.

FIG. 13 shows a multi-diode package 345 integrating at least the first diode 130 and the second diode 230. In the shared multi-diode package 345, the first diode 130 and the second diode 230 are exposed to the same temperature and temperature budget so that the identity or approximative identity of the device parameters is not compromised by different junction temperatures of the first diode 130 and the second diode 230.

If the first diode 130 and the second diode 230 are obtained from the same semiconductor die, the characteristic parameters of the first diode 130 and the second diode 230 can be to a high degree identical.

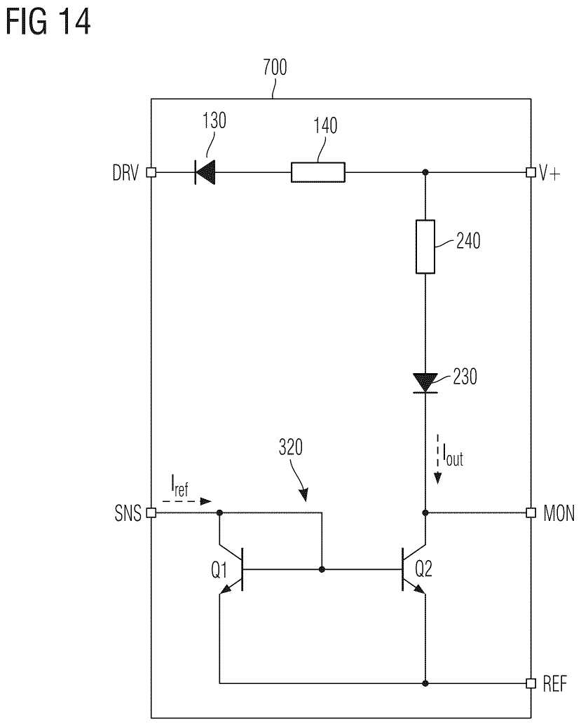

FIG. 14 shows an integrated gate driver support circuit 700 that integrates a current mirror circuit 320 with a first transistor Q1 and a second transistor Q2. The current mirror circuit 320 copies a reference current Iref through the first transistor Q1 by controlling an output current Iout through the second transistor Q2. A load path of the first transistor Q1 is electrically connected between a sense terminal SNS and a reference terminal REF. A base of the second transistor Q2 and a base of the first transistor Q1 are electrically connected to the sense terminal SNS. The emitter of the first transistor Q1 and the emitter of the second transistor Q2 are electrically connected to a reference terminal REF.

A first diode 130 and a first resistor 140 are electrically connected between a supply terminal V+ and a drive terminal DRV, wherein a cathode of the first diode 130 is oriented to the drive terminal DRV. A second diode 230 and a second resistor 240 are electrically connected between the supply terminal V+ and the collector of the second transistor Q2, wherein a cathode of the second diode 230 is oriented to the collector of the second transistor Q2. The collector of the second transistor Q2 is electrically connected to a monitor terminal MON. The first diode 130 and the second diode 230 have equal nominal characteristics. The first resistor 140 and the second resistor 240 have equal nominal resistances.

The integrated gate driver support circuit 700 may further include a voltage monitoring unit and/or a compensation pn junction as described above and can be used for each of the switching circuits described above.

### ASPECTS

The following provides an overview of some Aspects of the present disclosure:

Aspect 1: A switching circuit, comprising: a power semiconductor device in a switched current path between a switching node and a reference potential; and a current mirror circuit comprising a first transistor and a second transistor and configured to copy a reference current through the first transistor by controlling an output current through the second transistor, wherein the first transistor is electrically connected outside the switched current path and in series with the power semiconductor device in a first current path, the second transistor is connected in a second current path, and the first current path and the second current path are electrically connected in parallel.

Aspect 2: The switching circuit according to Aspect 1, further comprising: a voltage monitoring unit configured to monitor a voltage in the second current path.

Aspect 3: The switching circuit according to any of Aspects 1-2, further comprising: a compensation pn junction, wherein the compensation pn junction and the second transistor are electrically connected in series in the second current path.

Aspect 4: The switching circuit according to Aspect 3, wherein the compensation pn junction comprises an auxiliary transistor in diode configuration, and wherein a base-emitter junction or body-source junction of the auxiliary transistor and the second transistor are electrically connected in series.

Aspect 5: The switching circuit according to Aspect 3, wherein the compensation pn junction, the first transistor and the second transistor are integrated in a multi-device package.

Aspect 6: The switching circuit according to any of Aspects 1-5, further comprising: a voltage supply circuit configured to supply an auxiliary supply voltage across the first current path and the second current path.

Aspect 7: The switching circuit according to any of Aspects 1-6, wherein the first current path comprises further first electric elements and the second current path comprises further second electric elements, and wherein, for a predefined current, a first voltage drop across the further first electric elements and a second voltage drop across the further second electric elements are equal.

Aspect 8: The switching circuit according to any of Aspects 1-7, wherein an ohmic resistance in the first current path and an ohmic resistance in the second current path deviate from each other by no more than 5% of an average value of the ohmic resistances;

Aspect 9: The switching circuit according to Aspect 7, further comprising: a first diode in the first current path; and a second diode in the second current path, wherein the first diode is configured to block a blocking voltage across the power semiconductor device in an off-state of the power semiconductor device, wherein the first diode and the second diode are forward biased when the power switching device is in an on-state, and wherein the first diode and the second diode have equal nominal characteristics.

Aspect 10: The switching circuit according to Aspect 9, wherein the first diode and the second diode are integrated in a multi-diode package.

Aspect 11: The switching circuit according to Aspect 9, wherein the first transistor, the second transistor, the first diode, the second diode, the further first electric elements, and the further second electric elements are integrated in a multi-device package.

Aspect 12: The switching circuit according to any of Aspects 1-11, wherein the first transistor and the second transistor comprise bipolar junction transistors and an emitter of the first transistor and an emitter of the second transistor are directly electrically connected to each other.

Aspect 13: The switching circuit according to any of Aspects 1-12, wherein the first transistor and the second transistor comprise field effect transistors and a source of the first transistor and a source of the second transistor are directly electrically connected to each other.

Aspect 14: The switching circuit according to any of Aspects 1-13, wherein the first transistor and the second transistor comprise p channel field effect transistors or the first transistor and the second transistor comprise pnp bipolar junction transistors.

Aspect 15: The switching circuit according to Aspect 14, further comprising: a voltage monitoring unit configured to monitor a voltage across the second transistor.

Aspect 16: The switching circuit according to Aspect 3, wherein the first transistor and the second transistor comprise n channel field effect transistors or the first transistor and the second transistor comprise npn bipolar junction transistors.

Aspect 17: The switching circuit according to Aspect 16, further comprising: a voltage monitoring unit electrically connected to load electrodes of the second transistor and configured to monitor a voltage across the second transistor.

Aspect 18: The switching circuit according to Aspect 16, further comprising: a voltage monitoring unit configured to monitor a voltage between an anode side of the compensation pn junction and a network node of the first current path between the power semiconductor device and the first transistor.

Aspect 19: A power module unit, comprising: a switching circuit according to claim 15; and a gate driver circuit configured to drive a gate signal to a gate of the power semiconductor device, wherein the gate driver circuit and the voltage monitoring unit are integrated in a gate driver integrated circuit.

Aspect 20: A motor controller circuit, comprising: a switching circuit according to any of Aspects 15 to 18; and a motor control circuit configured to drive a H bridge comprising the power semiconductor device of the switching circuit, wherein the motor control circuit and the voltage monitoring unit are integrated in a motor controller integrated circuit.

Aspect 21: An integrated gate driver support circuit, comprising: a current mirror circuit comprising a first transistor and a second transistor and configured to copy a reference current through the first transistor by controlling an output current through the second transistor, wherein the first transistor is electrically connected between a sense terminal and a reference terminal; a first diode electrically connected between a supply terminal and a drive terminal, wherein a cathode of the first diode is oriented to the drive terminal; and a second diode electrically connected in series with the second transistor in a path between the supply terminal and the reference terminal, wherein an anode of the second diode is oriented to the supply terminal, and wherein the first diode and the second diode have equal nominal characteristics.

Aspect 22: A system configured to perform one or more operations recited in one or more of Aspects 1-21.

Aspect 23: An apparatus comprising means for performing one or more operations recited in one or more of Aspects 1-21.

1. A switching circuit, comprising:
a power semiconductor device in a switched current path between a switching node and a reference potential; and
a current mirror circuit comprising a first transistor and a second transistor and configured to copy a reference current through the first transistor by controlling an output current through the second transistor,
wherein the first transistor is electrically connected outside the switched current path and in series with the power semiconductor device in a first current, the second transistor is connected in a second current path, and the first current path and the second current path are electrically connected in parallel.

2. The switching circuit according to claim 1, further comprising:
a voltage monitoring unit configured to monitor a voltage in the second current path.

3. The switching circuit according to claim 1, further comprising:
a compensation pn junction, wherein the compensation pn junction and the second transistor are electrically connected in series in the second current path.

4. The switching circuit according to claim 3,
wherein the compensation pn junction comprises an auxiliary transistor in diode configuration, and
wherein a base-emitter junction or body-source junction of the auxiliary transistor and the second transistor are electrically connected in series.

5. The switching circuit according to claim 3, wherein the compensation pn junction, the first transistor and the second transistor are integrated in a multi-device package.

6. The switching circuit according to claim 1, further comprising:
a voltage supply circuit configured to supply an auxiliary supply voltage across the first current path and the second current path.

7. The switching circuit according to claim 1,
wherein the first current path comprises further first electric elements and the second current path comprises further second electric elements, and
wherein, for a predefined current, a first voltage drop across the further first electric elements and a second voltage drop across the further second electric elements are equal.

8. The switching circuit according to claim 1, wherein an ohmic resistance in the first current path and an ohmic resistance in the second current path deviate from each other by no more than 5% of an average value of the ohmic resistances.

9. The switching circuit according to claim 7, further comprising:
a first diode in the first current path; and
a second diode in the second current path,
wherein the first diode is configured to block a blocking voltage across the power semiconductor device in an off-state of the power semiconductor device,
wherein the first diode and the second diode are forward biased when the power switching device is in an on-state, and
wherein the first diode and the second diode have equal nominal characteristics.

10. The switching circuit according to claim 9, wherein the first diode and the second diode are integrated in a multi-diode package.

11. The switching circuit according to claim 9, wherein the first transistor, the second transistor, the first diode, the second diode, the further first electric elements and the further second electric elements are integrated in a multi-device package.

12. The switching circuit according to claim 1, wherein the first transistor and the second transistor comprise bipolar junction transistors and an emitter of the first transistor and an emitter of the second transistor are directly electrically connected to each other.

13. The switching circuit according to claim 1, wherein the first transistor and the second transistor comprise field effect transistors and a source of the first transistor and a source of the second transistor are directly electrically connected to each other.

14. The switching circuit according to claim 1, wherein the first transistor and the second transistor comprise p channel field effect transistors or the first transistor and the second transistor comprise pnp bipolar junction transistors.

15. The switching circuit according to claim 14, further comprising:
a voltage monitoring unit configured to monitor a voltage across the second transistor.

16. The switching circuit according to claim 3, wherein the first transistor and the second transistor comprise n channel field effect transistors or the first transistor and the second transistor comprise npn bipolar junction transistors.

17. The switching circuit according to claim 16, further comprising:
a voltage monitoring unit electrically connected to load electrodes of the second transistor and configured to monitor a voltage across the second transistor.

18. The switching circuit according to claim 16, further comprising:
a voltage monitoring unit configured to monitor a voltage between an anode side of the compensation pn junction and a network node of the first current path between the power semiconductor device and the first transistor.

19. A power module unit, comprising:
a switching circuit according to claim 15; and
a gate driver circuit configured to drive a gate signal to a gate of the power semiconductor device, wherein the gate driver circuit and the voltage monitoring unit are integrated in a gate driver integrated circuit.

20. (canceled)

21. An integrated gate driver support circuit, comprising:
a current mirror circuit comprising a first transistor and a second transistor and configured to copy a reference current through the first transistor by controlling an output current through the second transistor, wherein the first transistor is electrically connected between a sense terminal and a reference terminal;
a first diode electrically connected between a supply terminal and a drive terminal, wherein a cathode of the first diode is oriented to the drive terminal; and
a second diode electrically connected in series with the second transistor in a path between the supply terminal and the reference terminal,
wherein an anode of the second diode is oriented to the supply terminal, and
wherein the first diode and the second diode have equal nominal characteristics.
